(19) United States
(12) Patent Application Publication
(10) Pub. No.: US 2006/0046321 A1
(43) Pub. Date: Mar. 2, 2006

(54) Underfill injection mold

(75) Inventor: David W. Peters, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(73) Assignee: Hewlett-Packard Development Company, L.P.

(21) Appl. No.: 10/928,779

(22) Filed: Aug. 27, 2004

(51) Int. Cl. H01L 21/66

(52) U.S. Cl. 438/14

(57) ABSTRACT

An underfill injection mold includes an inner surface defining a cavity to receive injected underfill substantially between a first substrate and a second substrate. The cavity includes convex, curvilinear sidewalls to define a concave, curvilinear underfill fillet of the injected underfill. In an example, dimensions of the inner surface that define the underfill fillet are based upon a finite element analysis of the underfill.

### TECHNICAL FIELD

Embodiments of the present subject matter relate to an underfill injection mold.

### BACKGROUND

An active surface of a first substrate, such as a flip-chip, is subject to numerous electrical couplings that are usually brought to an edge of the first substrate. Heat generation is significant at the active surface of the first substrate. Electrical connections, referred variously to as balls, bumps, and others, are deposited as terminals on the active surface of a first substrate. The bumps include solders and/or plastics that make mechanical connections and electrical couplings to a second substrate, such as a printed circuit board. The first substrate is inverted onto the second substrate with the bumps aligned to bonding pads on the second substrate. If the bumps are solder bumps, the solder bumps on the first substrate are soldered to the bonding pads on the second substrate.

Shear stress may exist on the solder joints during temperature cycling of the device. This shear stress is partially a result of a difference in the coefficients of thermal expansion (“CTE”) of the first substrate and the second substrate.

It is desirable to reduce the shear stress on the solder joints to reduce failures.

### BRIEF DESCRIPTION OF THE DRAWINGS

FIG. 1 illustrates a top view of an example embodiment of a package in process.

FIG. 2 illustrates an example embodiment of a cross-section of the package of FIG. 1 through section 2-2.

FIG. 3 illustrates an example embodiment of a cross-section of the package of FIG. 2 with an underfill injection mold removed.

FIG. 4 illustrates an example embodiment of a cross-section of a package having an interposer with an underfill injection mold thereover.

FIG. 5 illustrates an example embodiment of a cross-section of the package of FIG. 4 with the underfill injection mold removed.

FIG. 6 illustrates a process flow diagram according to an example embodiment of a method to inject underfill for a package.

### DETAILED DESCRIPTION

The following description includes terms, such as “up”, “down”, “upper”, “lower”, “first”, “second”, etc. that are used for descriptive purposes only and are not to be construed as limiting. The embodiments of a device or article of the present invention described herein can be manufactured, used, or shipped in a number of positions and orientations.

The term “die” generally refers to the physical object that is the basic workpiece that is transformed by various process operations into the desired integrated circuit device. A die is usually singulated from a wafer, and wafers may be made of semiconducting, non-semiconducting, or combinations of semiconducting and non-semiconducting materials. The die may include a component body. The die may comprise semiconductive material, such as silicon, gallium arsenide, or germanium, and the substrate may include ceramic, such as alumina ceramic, or organic laminate material, such as FR-4 Laminate.

The term “substrate” used herein may generally refer to a printed circuit board, and/or a motherboard.

“Solder bumps” as used herein usually include substantially Pb-free solder technology, in example. In another example, the solder bumps are Pb-containing solder, or contain high-levels of Pb. By “substantially Pb-free solder”, it is meant that the solder is not designed with Pb content according to industry trends.

In an embodiment, connectors, such as solder connections, are reinforced by filling a gap between the die and the substrate, and by filling around the solder connections with underfill. The underfill may reduce joint failures due to stress during thermal cycling.

The effectiveness of an underfill mixture or composite depends on its chemical, physical, and mechanical properties. In an embodiment, the underfill mixture material is optimized to allow for fracture strength, adhesion, and/or crack mitigation for the fillet of the underfill. In an embodiment, underfill composites have coefficients of thermal expansion (CTEs) that are between the CTEs of the chip and the board. Underfill mixture properties may include low CTE, low moisture uptake, high toughness, high glass transition (Tg) temperature, high heat distortion temperature, a high modulus, a low viscosity at the time of injection, and good adhesion to the interfaces post cure so that no delamination at the interface occurs during device testing and field use. Accordingly, some embodiments include underfill mixtures that have a range of compositions and combinations.

According to various embodiments, the principal underfill compositions include at least one of silesquioxanes, thermosetting liquid crystal monomers, and mixtures thereof. Additive materials are included with the principal underfill compositions. The additive materials and the principal underfill compositions constitute “underfill mixtures” according to embodiments set forth herein. One additive material according to an embodiment is an elastomer for imparting flexibility to the principal underfill composition. Another additive material according to an embodiment is a hardener/crosslinker. The specific hardener/crosslinker that is employed will depend upon compatibility with the principal underfill composition. Hardeners/crosslinkers can be both aromatic and aliphatic in nature. The hardener/crosslinker in an embodiment is an anhydride composition. In another embodiment, the hardener/crosslinker is an amine.

Other additive materials according to embodiments may include one or more of a catalyst, a reactive diluent, an adhesion promoter, a flow modifier such as a surfactant, a deforming agent, a fluxing agent, a toughening agent that causes the underfill mixture to resist crack propagation, and an inorganic filler. The specific characteristics and composition of the underfill or fillet mixture that is employed will depend upon compatibility with the principal underfill or fillet composition.

FIG. 1 is a top view of an embodiment of a package or package assembly 100 in process. The package 100 includes a substrate 110 to support a die 120, which is electrically coupled to the substrate.

An underfill injection mold 130 is positioned over the die 120. In an embodiment, the underfill injection mold 130 includes an injection hole 132 into which underfill is injected between the die and the substrate. In an embodiment, the underfill is injected using an underfill dispenser positioned at the injection hole 132.

In an embodiment, the underfill injection mold 130 includes a vent or vacuum hole 134 to facilitate injection of the underfill between the die and the substrate. While the underfill is being flowed in a gap between the die and the substrate, the vent hole 134 allows air to escape and vent out, thereby increasing the speed of the underfill flow. In an additional embodiment, the diameter of the vent hole is in an approximate range of about 0.1 mm to about 2 mm.

In an embodiment, the pressure in the spaces to be filled with underfill material is atmospheric or negative pressure, such as a vacuum draw. There may be a pressure forcing the underfill material into the spaces to be filled. Injection of the underfill may be assisted by pumping the underfill composite between the die and the substrate, or by vacuum-assisted drawing of the underfill composite between the substrate and the die using the vacuum hole 134.

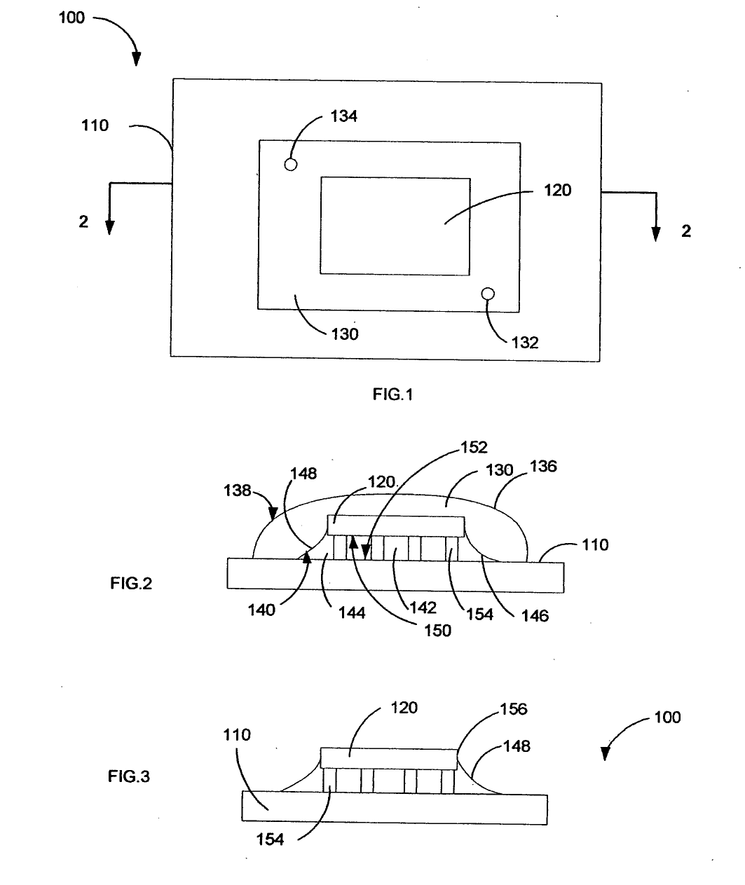

FIG. 2 is a cross-section of the package of FIG. 1 through section 2-2. The underfill injection mold 130 includes a body 136 having an outer surface 138 and an inner surface 140 defining a cavity 142 to receive injected underfill 144 substantially between the die 120 and the substrate 110. The cavity 142 includes convex, curvilinear sidewalls 146 to define a concave, curvilinear underfill fillet 148 of the injected underfill 144.

The die 120 includes an active surface 150 electrically coupled with a substrate surface 152 via solder connections 154. In an embodiment, solder bumps on the active surface are aligned and brought together with bond pads on the substrate surface. Next, reflow of the solder bumps is carried out to form the solder connections 154 to electrically and mechanically couple the die 120 and the substrate 110.

In the embodiment illustrated in FIG. 2, the solder connections 154 are reinforced by filling a gap or space or “standoff” between the die 120 and the substrate 110, and by filling around the connections 154, with the underfill 144. In an embodiment, the underfill 144 may act as a CTE intermediary for mismatched CTEs of the die and the substrate. In an embodiment, the underfill 144 substantially completely fills a volume between the die 120 and the substrate 110 so that the underfill 144 assists in supporting and protecting the die and the substrate.

In an embodiment, a depth of the cavity of the underfill injection mold 142 is larger than a standoff height between the substrate surface 152 and the active surface 150 of the die. In an embodiment, the standoff height is in an approximate range of from about 0.04 mm to about 0.1 mm in height. The depth of the cavity is larger than the standoff height in an embodiment as the inner surface 140 of the mold 130 extends from the substrate surface to side edges 156 of the die 120.

As shown in the embodiment of FIG. 3, the underfill includes the concave, curvilinear sloped fillet 148 from along side edges 156 of the die 120 down to the substrate surface 152. In an embodiment, the underfill fillet extends in an approximate range of from about ½ to about ⅔ up along the side edges 156 of the die down to the substrate surface 152.

The dimensions and shape of the inner surface 140 of the mold that form the underfill fillet 148 are based upon a finite element analysis in an embodiment. The finite element analysis method considers at least one of the following factors: characteristics of the underfill, a predetermined stress and strain on the underfill, a predetermined stress and strain on the solder connections, material characteristics of the die, material characteristics of the substrate, dimensions of the die, a shape and dimensions of the fillet, substrate real estate occupied by the fillet, a distance between the die and substrate, and a length of the fillet up along the side edges of the die. In an example embodiment, the die has a length in an approximate range of from about 5 mm to about 30 mm. In an embodiment, the components are considered to be large components. For example, the interposer, the die, and/or the substrate includes a dimension in an approximate range of from about 2 inches (about 5 cm) or larger.

In the embodiment illustrated in FIG. 1, the mold 130 does not completely cover the top surface of the die, or the top surface of the die can be viewed through the mold. In an additional embodiment illustrated in FIG. 2, the mold 130 encapsulates the die.

FIG. 3 is a cross-section of the package illustrated in FIG. 2 with the underfill injection mold 130 removed. In this embodiment, after the underfill 144 has cured, the injection mold 130 is removed. In this embodiment, a curing process is carried out to achieve the package assembly according to specific embodiments. The cure may include a thermal process, an autocatalytic process and/or a catalytic process.

In an embodiment, the curing process includes a one-part thermally cured underfill material. In an additional embodiment, the curing process includes a two-part material having an epoxy with an activator that may or may not be cured with an elevated temperature. For example, curing the underfill mixture may be done by an autocatalytic process. The autocatalytic process is carried out in an embodiment by providing a reactive diluent in the underfill mixture. In another embodiment, the curing process is carried out by an additive catalytic curing process. The additive catalytic curing process includes an additive such as a metal catalyst powder that causes the fillet and/or underfill mixtures to cure. In another embodiment, a cross-linking/hardening process is carried out to cure the underfill and/or fillet mixtures. Examples of specific cross-linker/hardener composition are set forth herein. In another embodiment, a thermoset curing process is carried out. Typically, several curing process embodiments are assisted by thermal treatment. However, in some embodiments, such as the use of a liquid crystal thermoset monomer, thermoset processing may be done without other curing agent processes.

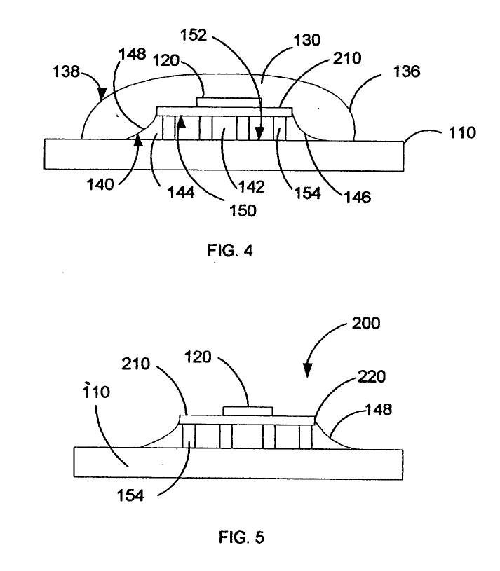

FIG. 4 illustrates an example embodiment of a cross-section of a package assembly 200 having an interposer 210 with the underfill injection mold 130 thereover. In an embodiment, the mold 130 encapsulates the die 120 and the interposer 210.

In FIGS. 2 and 4, and in FIGS. 3 and 5, like reference numerals describe substantially similar components in the different embodiments. Like reference numerals having different letter suffixes represent different instances of substantially similar components.

FIG. 4 illustrates an additional embodiment of a cross-section of the package assembly 200. The package assembly 200 includes the interposer 210 between the die and the substrate. The die 120 is electrically and mechanically coupled with the interposer 210 via connectors, in an embodiment. In an example embodiment, the connectors include reflowed solder bumps. The interposer 210 is electrically and mechanically coupled with the substrate 110 via interposer connectors, in an embodiment. In an example embodiment, the interposer connectors include solder connections.

The underfill injection mold 130 includes a body 136 having an outer surface 138 and an inner surface 140 defining a cavity 142 to receive injected underfill 144 substantially between the interposer 210 and the substrate 110. The cavity 142 includes convex, curvilinear sidewalls 146 to define a concave, curvilinear underfill fillet 148 of the injected underfill 144.

In the embodiment illustrated in FIG. 4, the solder connections are reinforced by filling a gap or space or “standoff” between the interposer 210 and the substrate 110, and by filling between adjacent solder connections with the underfill 144. In an embodiment, the underfill 144 may act as a CTE intermediary for mismatched CTEs of the interposer and the substrate. The underfill 144 may substantially completely fill a volume between the interposer 210 and the substrate 110 so that the underfill 144 assists in supporting and protecting the interposer and the substrate coupling.

In an embodiment, a depth of the cavity of the underfill injection mold 142 is larger than a standoff height between the substrate surface 152 and the interposer 210. In an embodiment, the standoff height is in an approximate range of from about 0.3 mm to about 1 mm in height. The depth of the cavity is larger than the standoff height in an embodiment as the inner surface 140 of the mold 130 extends from the substrate surface to side edges 220 of the interposer 210.

In an example embodiment, the interposer 210 has a length in an approximate range of from about 20 mm to about 60 mm. In an example embodiment, the die 120 has a length in an approximate range of from about 5 mm to about 30 mm. In an embodiment, the components are considered to be large components. For example, the die includes a dimension in an approximate range of from about 2 inches (about 5 cm) or larger.

The dimensions and shape of the inner surface 140 of the mold that form the underfill fillet 148 are based upon the finite element analysis in an embodiment. The finite element analysis method considers at least one of the following factors: characteristics of the underfill, a predetermined stress and strain on the underfill, a predetermined stress and strain on the interposer connectors, material characteristics of the interposer, material characteristics of the die, material characteristics of the substrate, dimensions of the die, dimensions of the interposer, a shape and dimensions of the fillet, substrate real estate occupied by the fillet, a distance between the interposer and the substrate, and a length of the fillet up along the interposer side edges.

As shown in the embodiment of FIG. 5, the underfill includes the concave, curvilinear sloped fillet 148 from along side edges 220 of the interposer 210 down to the substrate surface 152. In an embodiment, the underfill fillet extends in an approximate range of from about ½ to about ⅔ up along the side edges 220 down to the substrate surface 152.

FIG. 5 illustrates an example embodiment of a cross-section of the package assembly 200 of FIG. 4 with the underfill injection mold 130 removed. In this embodiment, after the underfill 144 has cured, the injection mold 130 is removed. In this embodiment, a curing process is carried out to achieve the package assembly 200 according to specific embodiments, as discussed herein.

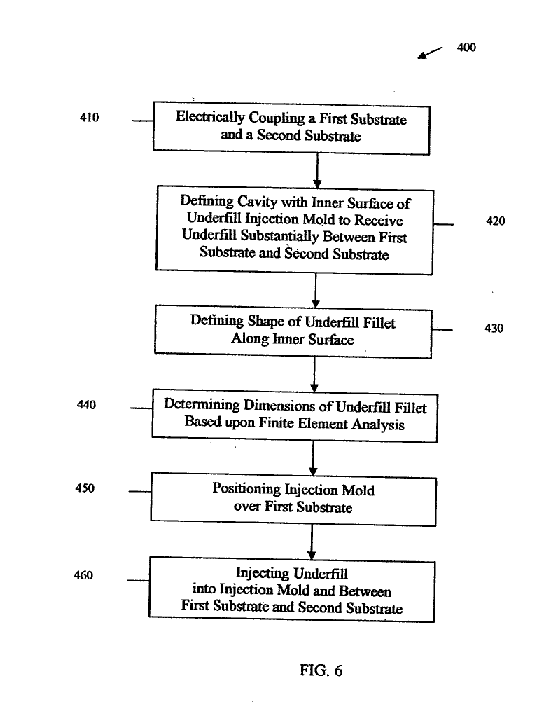

FIG. 6 illustrates a process flow diagram that depicts an embodiment of a packaging process at 400. At 410, an active surface of a die and a substrate surface are electrically coupled. At 420, a cavity with an inner surface of an underfill injection mold is defined to receive underfill substantially between the die and the substrate surface. At 430, a shape of an underfill fillet along the inner surface is defined. At 440, dimensions of the fillet are determined based upon finite element analysis. At 450, the injection mold is positioned over the die. At 460, the underfill is injected into the injection mold and between the die and the substrate. In embodiments, the underfill is injected by at least one of positive pressure expulsion, or negative pressure (vacuum) draw. After the underfill is cured, the injection mold is removed as shown in FIGS. 3 and 5.

FIGS. 1 to 6 are merely representational and are not drawn to scale. Certain proportions thereof may be exaggerated, while others may be minimized. Many other embodiments will be apparent to those of skill in the art upon reviewing the above description. Parts of some embodiments may be included in, or substituted for, those of other embodiments. While the foregoing examples of dimensions and ranges are considered typical, the various embodiments are not limited to such dimensions or ranges.

The illustrations of embodiments described herein are intended to provide a general understanding of the structure of various embodiments, and they are not intended to serve as a complete description of all the elements and features of apparatus and systems that might make use of the structures described herein. The accompanying drawings that form a part hereof show by way of illustration, and not of limitation, specific embodiments in which the subject matter may be practiced.

Applications that may include the apparatus and systems of various embodiments broadly include a variety of electronic and computer systems. The elements, materials, geometries, dimensions, and sequence of operations can all be varied to suit particular packaging requirements.

The packaging techniques described herein may be used with a die as described above, or with chip-scale packages, flash memory, SRAM, DRAM, ASICS, and PsuedoSRAM combinations. Therefore, such die packages could be part of system memory as well.

Embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The Abstract is provided to comply with 37 C.F.R. § 1.72(b) to allow the reader to quickly ascertain the nature and gist of the technical disclosure. The Abstract is submitted with the understanding that it will not be used to interpret or limit the scope or meaning of the claims.

In the foregoing Detailed Description, various features are grouped together in a single embodiment for the purpose of streamlining the disclosure. This method of disclosure is not to be interpreted as reflecting an intention that the claimed embodiments have more features than are expressly recited in each claim. Thus the following claims are hereby incorporated into the Detailed Description, with each claim standing on its own as a separate embodiment.

It will be readily understood to those skilled in the art that various other changes in the details, material, and arrangements of the parts and method stages which have been described and illustrated in order to explain the nature of embodiments herein may be made without departing from the principles and scope of embodiments as expressed in the subjoined claims.

What is claimed is:

1. A process comprising:
electrically coupling a surface of a first substrate with a surface of a second substrate, wherein a distance between the surfaces is in an approximate range of about 0.3 mm to about 1 mm;
defining a cavity with an inner surface of an underfill injection mold to receive underfill substantially between the first substrate and the second substrate;
defining a shape of an underfill fillet along the inner surface of the underfill injection mold;
determining dimensions of the inner surface that define the underfill fillet based upon a finite element analysis of the underfill;
positioning the injection mold over the first substrate; and
injecting the underfill into the injection mold and between the first substrate and the second substrate to form the underfill fillet.

2. The process of claim 1 further comprising curing the underfill and removing the injection mold.

3. The process of claim 1 wherein the injection mold includes at least one of a vacuum and a vent hole to facilitate injection of the underfill.

4. The process of claim 1 wherein the first substrate includes a dimension of at least about 20 mm.

5. The process of claim 1 wherein the fillet includes a concave, curvilinear slope from along side edges of the first substrate to the surface of the second substrate.

6. The process of claim 1 wherein the underfill fillet extends from about ½ to about ⅔ up along side edges of the first substrate down to the surface of the second substrate.

7. The process of claim 1 wherein the substrate comprises at least one of ceramic and an organic laminate material.

8. The process of claim 1 wherein the second substrate includes a printed circuit board, wherein the first substrate includes one of a die and an interposer between the die and the printed circuit board.

9. A process comprising:
electrically coupling a surface of a first substrate and a surface of a second substrate with connectors;
defining a cavity with an inner surface of an underfill injection mold to receive underfill substantially between the first substrate and the second substrate;
defining a shape of an underfill fillet along the inner surface of the underfill injection mold based upon a finite element analysis method of the underfill;
positioning the underfill injection mold over the first substrate; and
injecting underfill into the injection mold and between the first substrate and the second substrate to form the underfill fillet, wherein the underfill fillet extends in an approximate range from about ½ to about ⅔ up along side edges of the first substrate down to the surface of the second substrate.

10. The process of claim 9 further comprising curing the underfill and removing the injection mold.

11. The process of claim 9 wherein the injection mold includes at least one of a vacuum and a vent hole to facilitate injection of the underfill.

12. The process of claim 9 wherein the first substrate includes a dimension of at least about 20 mm.

13. The process of claim 9 wherein the underfill fillet includes a concave, curvilinear slope from along side edges of the first substrate to the surface of the second substrate.

14. The process of claim 9 wherein the finite element analysis method considers at least one of the following factors: characteristics of the underfill, a predetermined stress and strain on the underfill, a predetermined stress and strain on the connectors, material characteristics of the first substrate, material characteristics of the second substrate, dimensions of the first substrate, the shape of the fillet, second substrate real estate occupied by the fillet, a distance between the first substrate and the second substrate, and a length of the fillet up along the side edges of the first substrate.

15. A package formed in the process of claim 9.

16. A process comprising:
electrically coupling a surface of an interposer with a substrate surface;
defining a cavity with an inner surface of an underfill injection mold to receive underfill substantially between the interposer and the substrate surface;
defining a convex, curvilinear shape along the inner surface of the injection mold based upon a finite element analysis method of the underfill;
positioning the injection mold over the interposer; and
injecting the underfill into the injection mold and between the interposer and the substrate to form a concave, curvilinear, underfill fillet.

17. The process of claim 16 further comprising curing the underfill and removing the injection mold.

18. The process of claim 16 wherein the injection mold includes at least one of a vacuum and a vent hole to facilitate injection of the underfill.

19. The process of claim 16 wherein the curvilinear underfill fillet extends in an approximate range from about ½ to about ⅔ up along side edges of the interposer down to the substrate surface.

20. The process of claim 16 wherein the substrate comprises at least one of ceramic and an organic laminate material.

21. The process of claim 16 further comprising solder connections electrically coupling the interposer and the substrate.

22. An underfill injection mold comprising:
a body having an outer surface and an inner surface defining a cavity to receive injected underfill substantially between a first substrate and a second substrate, wherein the cavity includes convex, curvilinear sidewalls to define a concave, curvilinear underfill fillet of the injected underfill.

23. The underfill injection mold of claim 22 further comprising at least one of a vacuum and a vent hole to facilitate injection of the underfill.

24. The underfill injection mold of claim 22 wherein a depth of the cavity is larger than a distance from the first substrate to the second substrate and the concave, curvilinear underfill fillet extends in an approximate range of from about ½ to about ⅔ up along side edges of the first substrate down to the second substrate.

25. A system comprising:
a first substrate having a surface;
a substrate with a surface electrically coupled with the surface of the first substrate via connectors; and
an underfill injection mold having a body with an outer surface and an inner surface defining a cavity to receive injected underfill substantially between the first substrate and the second substrate, wherein the cavity includes convex, curvilinear sidewalls to define a concave, curvilinear underfill fillet of the injected underfill, wherein the curvilinear fillet extends from about ½ to about ⅔ up along side edges of the first substrate down to the surface of the second substrate.

26. The system of claim 25 wherein a depth of the cavity is larger than a distance from the first substrate to the surface of the second substrate.

27. The system of claim 25 wherein a shape of the fillet is based upon at least one of the following factors: characteristics of the underfill, a predetermined stress and strain on the underfill, a predetermined stress and strain on the connectors, material characteristics of the first substrate, material characteristics of the second substrate, dimensions of the first substrate, second substrate real estate occupied by the fillet, a distance between the first substrate and the second substrate, and a length of the fillet up along the side edges of the first substrate.
